(19) United States
(12) Patent Application Publication
(10) Pub. No.: US 2024/0003957 A1
(43) Pub. Date: Jan. 4, 2024

(54) METHOD FOR DETERMINING A LOCATION OF POWERLINE EVENTS AND SYSTEM AND DEVICE FOR IMPLEMENTING THE SAME

(71) Applicant: POWER MONITORS, INC., Mt. Crawford, VA (US)

(72) Inventors: Walter Morgan CURT, Mt. Crawford, VA (US); Christopher Fisher MULLINS, Mt. Crawford, VA (US)

(21) Appl. No.: 18/346,468

(22) Filed: Jul. 3, 2023

Related U.S. Application Data
(60) Provisional application No. 63/357,668, filed on Jul. 1, 2022.

(51) Int. Cl. G01R 31/08

(52) U.S. Cl. CPC G01R 31/088

(57) ABSTRACT

A process includes implementing a plurality of implementations of a power grid event monitor. Implementing at least one implementation of a power grid event analytics system. Connecting the plurality of implementations of the power grid event monitor to the power grid, where the power grid event monitor is a voltage monitor, a current monitor, and/or a voltage and current monitor. Where the plurality of implementations of the power grid event monitor are located in and electrically connected to certain respective implementations of a power grid component of the power grid.

### CROSS-REFERENCE TO RELATED APPLICATIONS

This application claims the benefit from U.S. Provisional Application No. 63/357,668 filed on Jul. 1, 2022, which is hereby incorporated by reference in its entirety for all purposes as if fully set forth herein.

### FIELD OF THE DISCLOSURE

The disclosure relates to a method for determining a location of powerline events. The disclosure further relates to a system for determining a location of powerline events. The disclosure further relates to a device for determining a location of powerline events.

### BACKGROUND OF THE DISCLOSURE

Many events on the power grid lead to unplanned outages, wildfires, and/or the like. The root cause of these events are often equipment failure, such as a failed splice, lighting arrestor, insulator, transformer insulation breakdown, and/or the like. Additionally, vegetative or animal contact with exposed conductors may cause faults. Fault conditions result in unplanned outage for electricity users, and may pose a fire risk, an electric shock risk, and/or the like.

Accordingly, a method, system, and/or device is needed to reduce issues with the power grid.

In many cases, faults and other types of failures happen gradually, with intermittent, brief faults occurring before a permanent failure. These brief faults or other powerline events may create signatures that can be used to predict or identify the nature of the problem, and also location. A method for location is disclosed here. In particular, a method for determining a location of powerline events, a system for determining a location of powerline events, and/or a device for determining a location of powerline events.

### SUMMARY OF THE DISCLOSURE

In one aspect, a power line event determination process includes implementing a plurality of implementations of a power grid event monitor. The power line event determination process in addition includes implementing at least one implementation of a power grid event analytics system. The process moreover includes connecting the plurality of implementations of the power grid event monitor to the power grid. The process also includes where the power grid event monitor is a voltage monitor, a current monitor, and/or a voltage and current monitor. The process further includes where the plurality of implementations of the power grid event monitor are located in and electrically connected to certain respective implementations of a power grid component of the power grid. The process in addition includes where the power grid component includes one of the following: power stations, electrical substations, electric power transmission components, powerlines, electric power distribution components, electricity generation components, generators, high-voltage substations, local substations, high voltage transmission lines, step-up substations, step-down substations, distribution substations, transformers, circuit breakers, switches, lightning arresters, capacitors, electric power distribution components, distribution lines, distribution transformers, and/or feeders.

In one aspect, a power line event determination system includes a plurality of implementations of a power grid event monitor. The power line event determination system in addition includes at least one implementation of a power grid event analytics system. The system moreover includes the plurality of implementations of the power grid event monitor connected to the power grid. The system also includes where the power grid event monitor is a voltage monitor, a current monitor, and/or a voltage and current monitor. The system further includes where the plurality of implementations of the power grid event monitor are located in and electrically connected to certain respective implementations of a power grid component of the power grid. The system in addition includes where the power grid component includes one of the following: power stations, electrical substations, electric power transmission components, powerlines, electric power distribution components, electricity generation components, generators, high-voltage substations, local substations, high voltage transmission lines, step-up substations, step-down substations, distribution substations, transformers, circuit breakers, switches, lightning arresters, capacitors, electric power distribution components, distribution lines, distribution transformers, and/or feeders.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a system implemented in a power grid according to aspects of the disclosure.

FIG. 2 illustrates an exemplary implementation of the system implemented in the power grid according to aspects of the disclosure.

FIG. 3 illustrates an exemplary implementation of a monitor according to aspects of the disclosure.

FIG. 4 illustrates an exemplary implementation of the power grid event analytics system according to aspects of the disclosure.

FIG. 5 illustrates a process for determining a location of powerline events according to aspects of the disclosure.

### DETAILED DESCRIPTION

The disclosure will now be described with reference to the drawing figures, in which like reference numerals refer to like parts throughout. Aspects of the disclosure advantageously provide a method for determining a location of powerline events, a system for determining a location of powerline events and/or a device for determining a location of powerline events.

Many types of failure mechanisms present precursor faults before the final, catastrophic failure. These may be full-current precursors, in which traditional impedance based location techniques may be attempted with data from a substation recorder or fault current indicator on a power line. In other cases, the precursor may not be at full fault current—it could be a high impedance fault, and only present data via a voltage disturbance, and/or the like. In addition, some fault current may be provided by distributed generation, making impedance based location difficult or impossible.

Instead of using fault current levels and impedance calculations to estimate distance to the fault, a method, system, and/or device is disclosed here to use the time of arrival difference from two different monitors to estimate location. This eliminates the need for impedance models, and the reliance of full fault current.

In one aspect, at least two voltage/current monitors are located on a power line. As an example, one monitor may be located at a substation on a specific feeder, and another at the end of the feeder. In the simplified case, there are no laterals on the feeder. Each monitor uses GPS or other timing methodology to sample the instantaneous voltage and current waveforms with sub-millisecond timing accuracy, for example a time accuracy of two microseconds or less. These monitors may be sampling continuously, with either triggering based on prior machine learning training information to match specific signatures, traditional waveshape triggering, such as RMS (root mean square) or peak value change or trigger, waveshape change based on THD (total harmonic distortion) or mean square difference from previous cycle, level trigger after high pass filtering or 60 Hz comb filtering, and/or the like.

When an event occurs on monitored feeder, the voltage and current disturbance will propagate through the feeder at a speed based on the velocity factor of the power line. The time of arrival at each monitor will depend on the distance to each monitor and the velocity factor. Given knowledge of the exact position of the monitor and length of power line, the relative times of arrival may be used to estimate the fault location. The total propagation time is the summation. For example, if the fault signature arrives at each monitor at the same time, the fault must be located in the middle of the feeder, equidistant to both monitors. Given the velocity factor (VF) of the feeder and the difference in arrival time T, a location estimation can be made, where c is the speed of light:

D=T×c×VF

In this regard, D is the distance from the monitor with the earlier time of arrival. A value of VF may be estimated from known events such as transformer energization, system switch operations, and/or the like.

Exact time of arrival may be based on time of peak current or voltage during the event, more sophisticated techniques such as cross correlating the received signal from one monitor with the other to find the correlation peak, and/or the like. Further, high pass filtering may be used to separate the high frequency signal from 60 Hz signals.

In one aspect, the monitors may be placed at the substation at a head of each feeder, and at each end of feeder line. Other embodiments may include implementations of the monitor on laterals to provide more estimation data. Any monitor that detects the disturbance provides another time of arrival data point. At least two implementations of the monitor are needed, any more create an over-determined system that adds to the reliability of the estimate.

Polyphase and symmetrical component techniques may also be used to increase accuracy depending on the nature of the fault (e.g. phase-phase or phase-ground).

In another embodiment, signals may be injected at known locations on the power line. These signals could be current pulses or voltage disturbances. Since the location is known, this allows for calibration of the value VF, reflections, and other sources of error from the monitors that detect the disturbance. In some embodiments, the monitors may be configured to inject these calibration pulses into the system as needed.

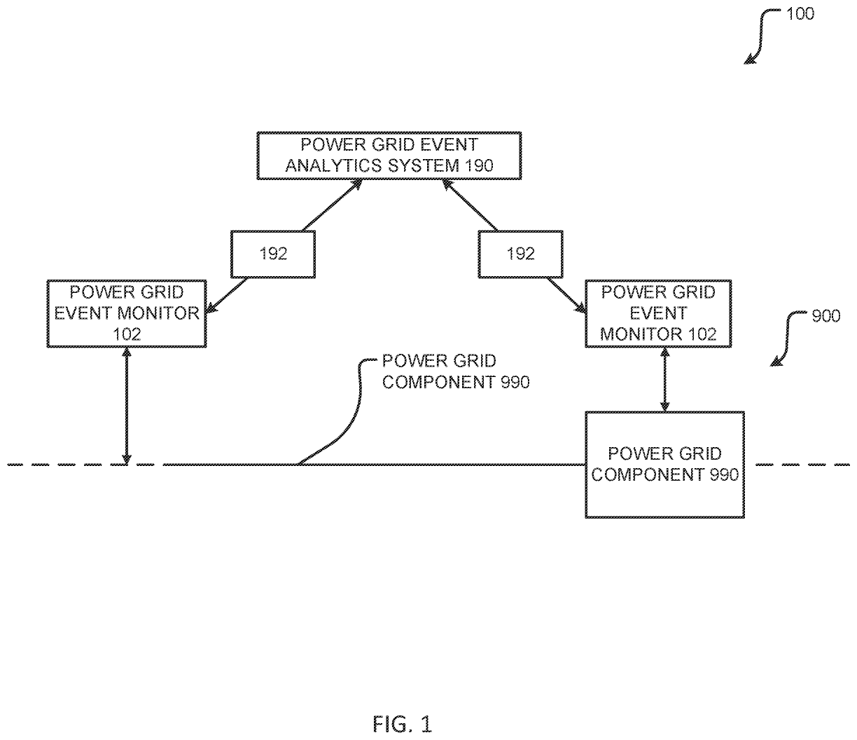

FIG. 1 illustrates a system implemented in a power grid according to aspects of the disclosure.

In particular, FIG. 1 illustrates a system 100 implemented in a power grid 900 according to aspects of the disclosure. The system 100 may be a power grid event detection system, a power grid fault detection system, and/or the like.

The system 100 may include a plurality of implementations of a power grid event monitor 102, at least one implementation of a power grid event analytics system 190, and/or the like. In aspects, the system 100 may include at least two implementations of the power grid event monitor 102 connected to the power grid 900. In aspects, there may be a plurality of implementations of the power grid event monitor 102 connected to the power grid 900. In aspects, the power grid event monitor 102 may be a voltage monitor, a current monitor, a voltage and current monitor, and/or the like. Further, the plurality of implementations of the power grid event monitor 102 may be located in and electrically connected to the power grid 900.

In particular, the power grid 900 may include a plurality of implementations of a power grid component 990. The plurality of implementations of the power grid event monitor 102 may be located in and electrically connected to certain respective implementations of the power grid component 990 of the power grid 900

The plurality of implementations of the power grid component 990 may include power stations, electrical substations, electric power transmission components, powerlines, electric power distribution components, electricity generation components, generators, high-voltage substations, local substations, high voltage transmission lines, step-up substations, step-down substations, distribution substations, transformers, circuit breakers, switches, lightning arresters, capacitors, electric power distribution components, distribution lines, distribution transformers, feeders, and/or the like.

As illustrated in FIG. 1, a first implementation of the power grid event monitor 102 may be located in and/or connected to a first implementation of the power grid component 990 of the power grid 900; and a second implementation of the power grid event monitor 102 may be located in and/or connected to a second implementation of the power grid component 990 of the power grid 900.

Each implementation of the power grid event monitor 102 may detect a fault criteria and generate fault data 192 that may include a time of fault and fault criteria. Thereafter, the power grid event monitor 102 may send the fault data 192 to the power grid event analytics system 190.

The power grid event monitor 102 may use GPS (Global Positioning System) or other timing methodology to generate the time of fault; and the power grid event monitor 102 may be configured to sample instantaneous voltage waveforms and/or current waveforms at a location of a respective implementation of the power grid component 990 within the power grid 900 that the particular implementation of the power grid event monitor 102 is located to generate the fault criteria. In aspects, the power grid event monitor 102 may sample instantaneous voltage waveforms and/or current waveforms with sub-millisecond timing accuracy, for example a time accuracy of two microseconds or less.

In aspects, the power grid event monitor 102 may be sampling continuously, with triggering based on prior machine learning training information to match the fault criteria. The fault criteria may include specific signatures, traditional waveshape triggering, such as RMS (root mean square) or peak value change or trigger, waveshape change based on THD (total harmonic distortion) or mean square difference from previous cycle, level trigger after high pass filtering or 60 Hz comb filtering, and/or the like.

When an event occurs on a portion of the power grid 900 that the power grid event monitor 102 is monitoring, such as a monitored feeder, the voltage and current disturbance will propagate through the power grid 900, such as a feeder line 902, at a speed based on the velocity factor of the component of the power grid 900, such as the feeder line 902. The time of arrival at each implementation of the power grid event monitor 102 will depend on a distance to each implementation of the power grid event monitor 102 and the velocity factor.

Given knowledge of the exact position of implementations of the power grid event monitor 102 and associated monitored implementations of the power grid component 990, the relative times of arrival may be used to estimate a fault location within the power grid 900. The total propagation time is the summation of the times.

For example, if the fault signature arrives at each implementation of the power grid event monitor 102 at the same time, the fault must be located equidistant to both implementations of the power grid event monitor 102. Given the velocity factor (VF) of the components of the power grid 900 between implementations of the power grid event monitor 102 and the difference in arrival time T, a location estimation of the fault can be made within the power grid 900 by the power grid event analytics system 190, where c is the speed of light:

D=T×c×VF

In this regard, D is the distance from implementations of the power grid event monitor 102 with the earlier time of arrival. A value of VF may be estimated from known events such as transformer energization, system switch operations, and/or the like. In this regard, the power grid event analytics system 190 may the fault data 192 from the various implementations of the power grid event monitor 102 in order to determine a location of a fault within the power grid 900.

Exact time of arrival may be based on time of peak current or voltage during the event, more sophisticated techniques such as cross correlating the received signal from one monitor with the other to find the correlation peak, and/or the like. Further, high pass filtering may be used to separate the high frequency signal from 60 Hz signals.

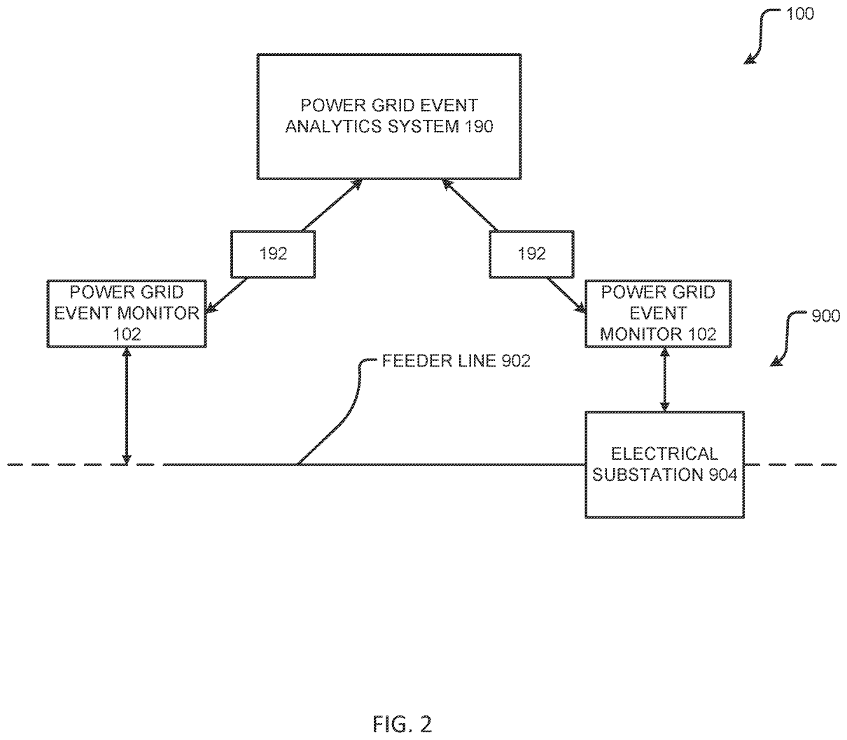

FIG. 2 illustrates an exemplary implementation of the system implemented in the power grid according to aspects of the disclosure.

In particular, FIG. 2 illustrates an exemplary implementation of the system 100 implemented in the power grid 900 according to aspects of the disclosure. In one aspect, implementations of the power grid event monitor 102 may be placed at any locations within the power grid 900, such as at the at least one electrical substation 904 at a head of each implementation of the feeder line 902, and at each end of the feeder line 902. Other embodiments may include implementations of the power grid event monitor 102 on laterals of the power grid 900 to provide more estimation data. Any additional implementations of the power grid event monitor 102 that detect the disturbance may provide another time of arrival data point, which may be provided to the power grid event analytics system 190. At least two implementations of the power grid event monitor 102 are needed, any more implementations of the system 100 to create an over-determined system that adds to the reliability of the estimate generated by the power grid event analytics system 190.

Polyphase and symmetrical component techniques may also be used by the power grid event monitor 102 and/or the power grid event analytics system 190 to increase accuracy depending on the nature of the fault within the power grid 900, such as phase-phase, phase-ground, and/or the like.

In another embodiment, the power grid event monitor 102 may be configured to generate signals that may be injected at known locations within the power grid 900, such as on the feeder line 902. These signals could be current pulses, voltage disturbances, and/or the like. Since the location is known, this allows for calibration of the value VF, reflections, and other sources of error by the power grid event analytics system 190 from the system 100 to that detect the disturbance. In some embodiments, the system 100 to may be configured to inject these calibration pulses into the power grid 900 as needed.

For example, the power grid event monitor 102 may be located in and/or connected to the feeder line 902 and/or the at least one electrical substation 904. As an example, one implementation of the power grid event monitor 102 may be located at the at least one electrical substation 904 on a specific implementation of the feeder line 902, and another implementation of the power grid event monitor 102 at the end of the feeder line 902. In the simplified case, there are no laterals on the feeder line 902.

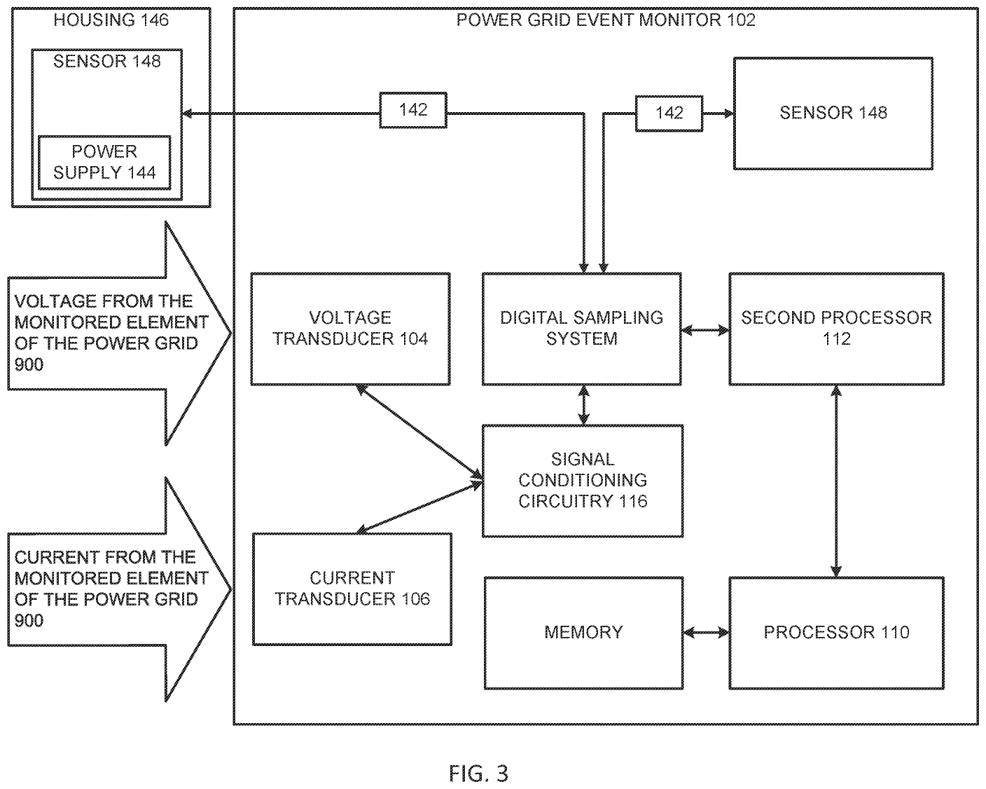

FIG. 3 illustrates an exemplary implementation of a monitor according to aspects of the disclosure.

With reference to FIG. 3, the power grid event monitor 102 may include a voltage transducer 104, a current transducer 106, an ND (analog to digital) converter, and/or the like. In aspects, the voltage transducer 104 may be configured to measure an electrical parameter such as a voltage associated with the monitored implementation of the power grid component 990 of the power grid 900. In this regard, the voltage transducer 104 may be configured with components, circuits, and/or the like for voltage measurement.

In aspects, the current transducer 106 may be configured to measure an electrical parameter such as a current associated with the monitored implementation of the power grid component 990 of the power grid 900. In this regard, the current transducer 106 may be configured with components, circuits, and/or the like for current measurement.

In aspects, the power grid event monitor 102 may include multiple implementations of the voltage transducer 104. In aspects, the power grid event monitor 102 may include multiple implementations of the current transducer 106. In aspects, the power grid event monitor 102 may include multiple implementations of the voltage transducer 104 and multiple implementations of the current transducer 106. In aspects, the power grid event monitor 102 may include one or more implementations of the voltage transducer 104 without any implementations of the current transducer 106. In aspects, the power grid event monitor 102 may include one or more implementations of the current transducer 106 without any implementations of the voltage transducer 104.

With further reference to FIG. 3, the power grid event monitor 102 may include at least one sensor 148 and/or may connect to at least one sensor 148. In aspects, the at least one sensor 148 may collect sensor readings and provide the sensor readings to the power grid event analytics system 190, the power grid event monitor 102, signal conditioning circuitry 116, and/or the like. In particular, the at least one sensor 148 may be implemented as one or more of a temperature sensor, an air pressure sensor, a humidity sensor, a solar flux sensor, a vibration sensor, and/or the like.

The at least one sensor 148 may include a housing 146, a power supply 144, a wired or wireless connection 142, and/or the like. The housing 146 may be configured as an enclosure for protecting the at least one sensor 148, the power supply 144, the wired or wireless connection 142, and/or the like from the surrounding environment. The housing 146 may include various features to protect and provide access to the at least one sensor 148, the power supply 144, the wired or wireless connection 142, and/or the like. In one aspect, the housing 146 may include access features, such as a door, to access the at least one sensor 148, connections to the at least one sensor 148, the power supply 144, and/or the like. In aspects, the door may include a hinge structure to allow movement of the door as well as a mechanism to maintain the door in a closed position. Additionally, the housing 146 may include a sensor to monitor access to the housing 146 and/or the at least one sensor 148 and provide sensor outputs as part of the sensor readings. In aspects, the sensor may be a door closure sensor, a magnetic door closure sensor, and/or the like.

The power supply 144 may provide power to the at least one sensor 148 for sensor operation, the wired or wireless connection 142 for communication operation, and/or the like. In aspects, the power supply 144 may be implemented as a battery, a wired power connection to a separate power supply such as a power supply from the power grid event monitor 102, and/or the like. Battery implementations of the power supply 144 may be configured for long life. For example, battery implementations of the power supply 144 may be configured for up to 10 years of usage of the at least one sensor 148.

The wired or wireless connection 142 may be configured to receive the sensor readings from the at least one sensor 148 and provide the sensor readings to the power grid event analytics system 190 and/or the like on a communication channel as defined herein. In one aspect, the wired or wireless connection 142 may include a module to operate on a communication channel is defined herein, a Wi-Fi (wireless fidelity) module, a BLE (Bluetooth Low Energy) module, and/or the like that allows for connection to the power grid event analytics system 190 and/or the like.

The at least one sensor 148 may be implemented as a temperature sensor configured to measure an ambient temperature of the monitored element of the power grid 900, the power grid event monitor 102, the power grid event analytics system 190, an environment thereof, and/or the like. In aspects, implementation of the at least one sensor 148 as a temperature sensor may include implementations as a thermistor, a thermally sensitive resistor, a negative temperature coefficient (NTC) thermistor, a positive temperature coefficient (PTC) thermistor, a thermocouple, a resistance thermometer, a silicon bandgap temperature sensor, and/or the like.

The at least one sensor 148 may be implemented as an air pressure sensor configured to measure an ambient air pressure of the monitored element of the power grid 900, the power grid event monitor 102, the power grid event analytics system 190, an environment thereof, and/or the like. In aspects, implementation of the at least one sensor 148 as an air pressure sensor may include implementations as microelectromechanical system (MEMS) barometer, a piezoresistive pressure-sensing device, and/or the like.

The at least one sensor 148 may be implemented as a humidity sensor configured to measure an ambient humidity of the monitored element of the power grid 900, the power grid event monitor 102, the power grid event analytics system 190, an environment thereof, and/or the like. In aspects, implementation of the at least one sensor 148 as humidity sensor may include implementations as a capacitive hygrometer, a resistive hygrometer, a thermal hygrometer, a gravimetric hygrometer, optical hygrometer, and/or the like.

The at least one sensor 148 may be implemented as a solar flux sensor configured to measure an ambient solar flux in an environment of the monitored element of the power grid 900, the power grid event monitor 102, the power grid event analytics system 190, and/or the like. In aspects, implementation of the at least one sensor 148 as a solar flux sensor may include implementations as a photodiode, a thermopile pyranometer, photovoltaic pyranometer, a silicon photodiode, a photovoltaic cell, and/or the like.

The at least one sensor 148 may be implemented as a vibration sensor configured to measure an ambient vibration of the monitored element of the power grid 900, the power grid event monitor 102, the power grid event analytics system 190, an environment thereof, and/or the like. In aspects, implementation of the at least one sensor 148 as a vibration sensor may include implementations as a laser accelerometer, a piezoelectric accelerometer, a strain gauge accelerometer, a surface acoustic wave (SAW) accelerometer, a surface micromachined capacitive (MEMS) accelerometer, a potentiometric type accelerometer, and/or the like.

The at least one sensor 148 may be implemented as a wind speed and/or wind direction sensor configured to measure an ambient wind speed and/or wind direction in an environment of the monitored element of the power grid 900, the power grid event monitor 102, the power grid event analytics system 190, and/or the like. In aspects, implementation of the at least one sensor 148 as a wind speed and/or wind direction sensor may include implementations as an ultrasonic wind speed and/or wind direction sensor, a cup anemometer, a vane anemometer, a hot-wire anemometer, a laser doppler anemometer, an ultrasonic anemometer, an acoustic resonance anemometer, a ping-pong ball anemometer, a pressure anemometer, a plate anemometer, a tube anemometer, a pitot tube static anemometer, and/or the like. In aspects, implementation of the at least one sensor 148 as a wind speed and/or wind direction sensor may be configured without moving parts.

The at least one sensor 148 may be implemented as a rainfall/precipitation sensor configured to measure an ambient rainfall/precipitation in an environment of the monitored element of the power grid 900, the power grid event monitor 102, the power grid event analytics system 190, and/or the like. In aspects, implementation of the at least one sensor 148 as a rainfall/precipitation sensor may include implementations as an ultrasonic rain gauge, an acoustic rain gauge, an optical rain gauge, a weighing precipitation gauge, and/or the like. In aspects, implementation of the at least one sensor 148 as a rainfall/precipitation sensor may be configured without moving parts.

The at least one sensor 148 may be implemented to measure other environmental quantities, other physical quantities, and/or the like in an environment of the monitored element of the power grid 900, the power grid event monitor 102, the power grid event analytics system 190, and/or the like. In aspects, implementation of the at least one sensor 148 to measure other environmental quantities, other physical quantities, and/or the like may be configured without moving parts.

In aspects, the power grid event monitor 102 may include a processor 110, such as a DSP (digital signal processor). The processor 110 may be configured for data collection, pre-processing, analytic operations, and/or the like. The power grid event monitor 102 may include a second processor 112. The second processor 112 may be configured for data buffering, communication, and/or the like.

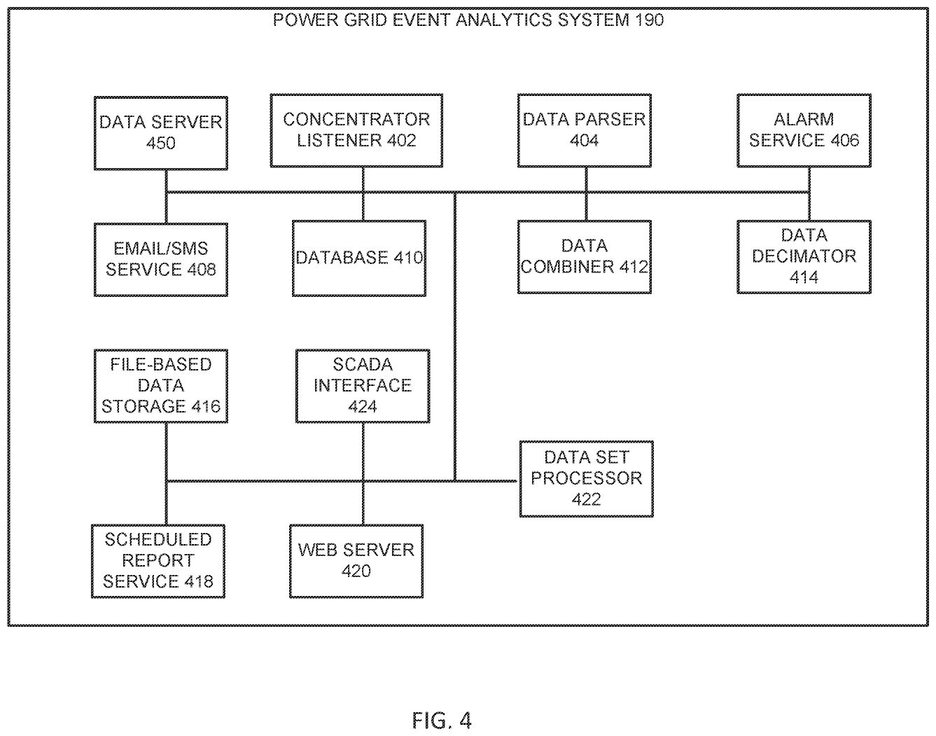

FIG. 4 illustrates an exemplary implementation of the power grid event analytics system according to aspects of the disclosure.

In particular, FIG. 4 illustrates an exemplary implementation of the power grid event analytics system 190 that may be implemented as a processor, a server, a cloud-based server system, a collection of virtual machines and processes, and/or the like. The power grid event analytics system 190 may be configured perform several functions: receive and parse the fault data 192 from one or more implementations of the power grid event monitor 102 as it streams in to the power grid event analytics system 190; store the fault data 192 as sent from the power grid event monitor 102; process any alerts from the power grid event monitor 102, including sending immediate message notices, such as email notices, text message notices, application based notices, and/or the like to a user device, to any triggered distribution list of user devices; provides a map-based graphical display of all the power grid event monitor 102 associated with a specific account to a user device; provide graphical and report-based data analysis tools for the user to view and analyze data on a user device; provide a control interface to send commands or query status of the power grid event monitor 102, or any other compatible device connected to the power grid event monitor 102 and/or the power grid event analytics system 190; and/or provide a SCADA system interface to allow an external SCADA master to query information and send commands to the power grid event monitor 102.

The power grid event analytics system 190 may further include one or more the following components, a data server 450, a concentrator listener 402, a data parser 404, an alarm service 406, an email/SMS service 408, a database 410, a data combiner 412, a data decimator 414, a file-based data storage 416, a scheduled report service 418, a Web server 420, a data set processor 422, a SCADA interface 424, and/or the like.

The user interaction with the power grid event analytics system 190 may be through a standard web browser. The power grid event analytics system 190 may utilize any other similar on-demand cloud computing platforms. An aspect may include a collection of Berkeley Software Distribution (BSD) or Linux-based virtual machine servers, including a server for receiving and parsing incoming packets from the power grid event monitor 102, storing received measurements, processing and sending alert emails and SMS messages, storing device information, user information, account information, billing information, and/or the like in a SQL database, and providing web hosting (e.g. with Apache) for the user web application. In aspects the servers are connected in a private network, with only the web host including a separate, public network interface (to allow web browser connections). The power grid event monitor 102 may be networked inside a cell carrier private network, with a VPN connection to the data server 450.

The data server 450 may decompress data received from the power grid event monitor 102 and may store the fault data 192. Although the data may be stored in a relational database, an aspect uses a binary file format to store individual packets. A separate combiner process may run in the background, reading the small, stored packets and combining them into larger chunks (e.g. into a 24 hour chunk).

A web application hosted by the power grid event analytics system 190 may present a map-based display of all implementations of the power grid event monitor 102 in a user's account. The power grid event monitor 102 may be located at the monitored implementation of the power grid component 990 of the power grid 900 manually by the user, or automatically located by using a global navigation satellite system (GNSS) such as GPS, or other positioning information sent by the power grid event monitor 102. A related heat map may be created from the analyzed data by the power grid event analytics system 190, the power grid event monitor 102, and/or the like to show detected or predicted problem areas graphically overload on a geographic map of the area. Utility-supplied GIS (Graphical Information system) data with the location of utility assets and historical problem locations may be overlaid or combined with the analyzed data on a heat map.

The web page may be used to request the generation of reports in various formats (HTML, CSV, PDF, etc.) These reports may be raw measurements from one or more implementations of the power grid event monitor 102, alert history, account billing information, etc. The reports may be rendered immediately and presented to the user in the browser, or configured to be emailed on a scheduled basis.

The power grid event analytics system 190 may be configured to present an external interface, to allow a connection to a 3rd party SCADA system or other control system. The external interface may be configured to use a standard SCADA protocol such as DNP, MODBUS over IP, and/or the like and may be configured to present device slave addresses and point maps such that the external SCADA system may poll or send commands to the power grid event analytics system 190. The power grid event monitor 102 and/or the power grid event analytics system 190 may parse SCADA messages, responding as needed. These commands and queries may be for data stored on the power grid event analytics system 190, or require the power grid event analytics system 190 to issue commands to various implementations of the power grid event monitor 102. For example, an operator may send a SCADA command to operate a component of the monitored implementation of the power grid component 990 of the power grid 900 from an outside system. This command may be received by the power grid event analytics system 190, processed, and relayed to the power grid event monitor 102.

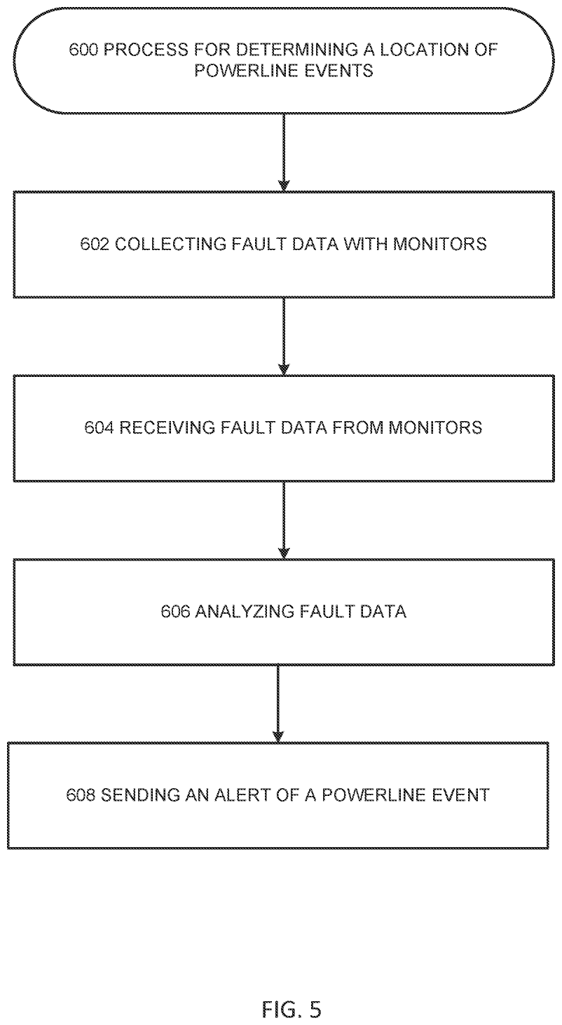

FIG. 5 illustrates a process for determining a location of powerline events according to aspects of the disclosure.

In particular, FIG. 5 illustrates a process for determining a location of powerline events 600 which may include any one or more the features described herein. The process for determining a location of powerline events 600 may be implemented by any component of the power grid event monitor 102 and/or the power grid event analytics system 190. The process for determining a location of powerline events 600 may be implemented by software.

The process for determining a location of powerline events 600 may include collecting fault data with monitors 602. In particular, the collecting fault data with monitors 602 may include collecting the fault data 192 with a plurality of implementations of the power grid event monitor 102 as described herein.

The process for determining a location of powerline events 600 may include receiving fault data from monitors 604. In particular, the receiving fault data from monitors 604 may include receiving the fault data 192 from a plurality of implementations of the power grid event monitor 102 as described herein.

The process for determining a location of powerline events 600 may include analyzing fault data 606. In particular, the analyzing fault data 606 may include analyzing the fault data 192 by the power grid event monitor 102 and/or the power grid event analytics system 190 as described herein.

The process for determining a location of powerline events 600 may include sending an alert of a powerline event 608. In particular, based on the collecting fault data with a monitor 602, the receiving fault data from a monitor 604, and the analyzing fault data 606, the process for determining a location of powerline events 600 may implement a process that includes the sending an alert of a powerline event 608 to a user device as described herein.

Accordingly, the disclosure has disclosed a method, system, and/or device to reduce issues with the power grid.

The following are a number of nonlimiting EXAMPLES of aspects of the disclosure.

One EXAMPLE: a power line event determination process includes implementing a plurality of implementations of a power grid event monitor. The power line event determination process in addition includes implementing at least one implementation of a power grid event analytics system. The process moreover includes connecting the plurality of implementations of the power grid event monitor to the power grid. The process also includes where the power grid event monitor is a voltage monitor, a current monitor, and/or a voltage and current monitor. The process further includes where the plurality of implementations of the power grid event monitor are located in and electrically connected to certain respective implementations of a power grid component of the power grid. The process in addition includes where the power grid component includes one of the following: power stations, electrical substations, electric power transmission components, powerlines, electric power distribution components, electricity generation components, generators, high-voltage substations, local substations, high voltage transmission lines, step-up substations, step-down substations, distribution substations, transformers, circuit breakers, switches, lightning arresters, capacitors, electric power distribution components, distribution lines, distribution transformers, and/or feeders.

The above-noted EXAMPLE may further include any one or a combination of more than one of the following EXAMPLES:

The power line event determination process of the above-noted EXAMPLE where a first implementation of the power grid event monitor is located in and/or connected to a first implementation of the power grid component of the power grid; and where a second implementation of the power grid event monitor is located in and/or connected to a second implementation of the power grid component of the power grid. The power line event determination process of the above-noted EXAMPLE where the power grid event monitor is configured to detect a fault criteria and generate fault data that includes a time of fault and fault criteria; and where the power grid event monitor is configured to send the fault data to the power grid event analytics system. The power line event determination process of the above-noted EXAMPLE where the power grid event monitor uses a GPS (Global Positioning System) or other timing methodology to generate the time of fault; and where the power grid event monitor is configured to sample instantaneous voltage waveforms and/or current waveforms at a location of a respective implementation of the power grid component within the power grid that a particular implementation of the power grid event monitor is located to generate the fault criteria. The power line event determination process of the above-noted EXAMPLE where the power grid event monitor is configured to sample continuously, with triggering based on prior machine learning training information to match the fault criteria; and where the fault criteria includes specific signatures, traditional waveshape triggering, such as RMS (root mean square) or peak value change or trigger, waveshape change based on THD (total harmonic distortion) and/or mean square difference from previous cycle, level trigger after high pass filtering or Hz comb filtering. The power line event determination process of the above-noted EXAMPLE where the power grid event analytics system is implemented with a processor; where the power grid event analytics system is configured to receive and parse the fault data from one or more implementations of the power grid event monitor; and where the power grid event analytics system is configured process alerts from the power grid event monitor. The power line event determination process of the above-noted EXAMPLE where the power grid event monitor is configured to sample instantaneous voltage waveforms and/or current waveforms with sub-millisecond timing accuracy. The power line event determination process of the above-noted EXAMPLE the power grid event analytics system is configured to utilize relative times of arrival a fault signature to estimate a fault location within the power grid. The power line event determination process of the above-noted EXAMPLE where an implementation of the power grid event monitor is placed at an electrical substation at a head of each implementation of a feeder line, and an implementation of the power grid event monitor is placed at an end of the feeder line. The power line event determination process of the above-noted EXAMPLE where the power grid event monitor includes a voltage transducer, a current transducer, and an A/D (analog to digital) converter. The power line event determination process of the above-noted EXAMPLE where the current transducer is configured to measure a current associated with the power grid component of the power grid; and where the voltage transducer is configured to measure a voltage associated with the power grid component of the power grid. The power line event determination process of the above-noted EXAMPLE where the power grid event monitor is configured to collect sensor readings and provide the sensor readings to the power grid event analytics system.

One EXAMPLE: the power line event determination system includes a plurality of implementations of a power grid event monitor. The power line event determination system in addition includes at least one implementation of a power grid event analytics system. The system moreover includes the plurality of implementations of the power grid event monitor connected to the power grid. The system also includes where the power grid event monitor is a voltage monitor, a current monitor, and/or a voltage and current monitor. The system further includes where the plurality of implementations of the power grid event monitor are located in and electrically connected to certain respective implementations of a power grid component of the power grid. The system in addition includes where the power grid component includes one of the following: power stations, electrical substations, electric power transmission components, powerlines, electric power distribution components, electricity generation components, generators, high-voltage substations, local substations, high voltage transmission lines, step-up substations, step-down substations, distribution substations, transformers, circuit breakers, switches, lightning arresters, capacitors, electric power distribution components, distribution lines, distribution transformers, and/or feeders.

The above-noted EXAMPLE may further include any one or a combination of more than one of the following EXAMPLES:

The power line event determination system of the above-noted EXAMPLE where a first implementation of the power grid event monitor is located in and/or connected to a first implementation of the power grid component of the power grid; and where a second implementation of the power grid event monitor is located in and/or connected to a second implementation of the power grid component of the power grid. The power line event determination system of the above-noted EXAMPLE where the power grid event monitor is configured to detect a fault criteria and generate fault data that includes a time of fault and fault criteria; and where the power grid event monitor is configured to send the fault data to the power grid event analytics system. The power line event determination system of the above-noted EXAMPLE where the power grid event monitor uses a GPS (Global Positioning System) or other timing methodology to generate the time of fault; and where the power grid event monitor is configured to sample instantaneous voltage waveforms and/or current waveforms at a location of a respective implementation of the power grid component within the power grid that a particular implementation of the power grid event monitor is located to generate the fault criteria. The power line event determination system of the above-noted EXAMPLE where the power grid event monitor is configured to sample continuously, with triggering based on prior machine learning training information to match the fault criteria; and where the fault criteria includes specific signatures, traditional waveshape triggering, such as RMS (root mean square) or peak value change or trigger, waveshape change based on THD (total harmonic distortion) and/or mean square difference from previous cycle, level trigger after high pass filtering or Hz comb filtering. The power line event determination system of the above-noted EXAMPLE where the power grid event analytics system is implemented with a processor; where the power grid event analytics system is configured to receive and parse the fault data from one or more implementations of the power grid event monitor; and where the power grid event analytics system is configured process alerts from the power grid event monitor. The power line event determination system of the above-noted EXAMPLE where the power grid event monitor is configured to sample instantaneous voltage waveforms and/or current waveforms with sub-millisecond timing accuracy. The power line event determination system of the above-noted EXAMPLE the power grid event analytics system is configured to utilize relative times of arrival a fault signature to estimate a fault location within the power grid. The power line event determination system of the above-noted EXAMPLE where an implementation of the power grid event monitor is placed at an electrical substation at a head of each implementation of a feeder line, and an implementation of the power grid event monitor is placed at an end of the feeder line. The power line event determination system of the above-noted EXAMPLE where the power grid event monitor includes a voltage transducer, a current transducer, and an ND (analog to digital) converter. The power line event determination system of the above-noted EXAMPLE where the current transducer is configured to measure a current associated with the power grid component of the power grid; and where the voltage transducer is configured to measure a voltage associated with the power grid component of the power grid. The power line event determination system of the above-noted EXAMPLE where the power grid event monitor is configured to collect sensor readings and provide the sensor readings to the power grid event analytics system.

The power grid event monitor 102 and/or the power grid event analytics system 190 may utilize artificial intelligence and/or machine learning and may utilize any number of approaches including one or more of cybernetics and brain simulation, symbolic, cognitive simulation, logic-based, anti-logic, knowledge-based, sub-symbolic, embodied intelligence, computational intelligence and soft computing, machine learning and statistics, and the like.

Aspects of the power grid event monitor 102 and/or the power grid event analytics system 190 may implement devices that may include communication channels that may be any type of wired or wireless electronic communications network, such as, e.g., a wired/wireless local area network (LAN), a wired/wireless personal area network (PAN), a wired/wireless home area network (HAN), a wired/wireless wide area network (WAN), a campus network, a metropolitan network, an enterprise private network, a virtual private network (VPN), an internetwork, a backbone network (BBN), a global area network (GAN), the Internet, an intranet, an extranet, an overlay network, Near field communication (NFC), a cellular telephone network, a Personal Communications Service (PCS), using known protocols such as the Global System for Mobile Communications (GSM), CDMA (Code-Division Multiple Access), GSM/EDGE and UMTS/HSPA network technologies, Long Term Evolution (LTE), 5G (5th generation mobile networks or 5th generation wireless systems), WiMAX, HSPA+, W-CDMA (Wideband Code-Division Multiple Access), CDMA2000 (also known as C2K or IMT Multi-Carrier (IMT-MC)), Wireless Fidelity (Wi-Fi), Bluetooth, and/or the like, and/or a combination of two or more thereof. The NFC standards cover communications protocols and data exchange formats, and are based on existing radio-frequency identification (RFID) standards including ISO/IEC 14443 and FeliCa. The standards include ISO/IEC 18092[3] and those defined by the NFC Forum.

Further in accordance with various aspects of the disclosure, the methods described herein are intended for operation with dedicated hardware implementations including, but not limited to, PCs, PDAs, semiconductors, application specific integrated circuits (ASIC), programmable logic arrays, cloud computing devices, and other hardware devices constructed to implement the methods described herein.

According to an example, the power grid event monitor 102 may be configured to receive signals from a global navigation satellite system (GNSS) may include a device and/or system that may estimate time and its location based, at least in part, on signals received from space vehicles (SVs). In particular, such a device and/or system may obtain “pseudorange” measurements including approximations of distances between associated SVs and a navigation satellite receiver. In a particular example, such a pseudorange may be determined at a receiver that is capable of processing signals from one or more SVs as part of a Satellite Positioning System (SPS). Such an SPS may comprise, for example, a Global Positioning System (GPS), Galileo, Glonass, to name a few, or any SPS developed in the future. To determine its location, a satellite navigation receiver may obtain pseudorange measurements to three or more satellites as well as their positions at time of transmitting. Knowing the SV orbital parameters, these positions can be calculated for any point in time. A pseudorange measurement may then be determined based, at least in part, on the time a signal travels from an SV to the receiver, multiplied by the speed of light. While techniques described herein may be provided as implementations of location determination in GPS and/or Galileo types of SPS as specific illustrations according to particular examples, it should be understood that these techniques may also apply to other types of SPS, and that claimed subject matter is not limited in this respect.

It should also be noted that the software implementations of the disclosure as described herein are optionally stored on a tangible storage medium, such as: a magnetic medium such as a disk or tape; a magneto-optical or optical medium such as a disk; or a solid state medium such as a memory card or other package that houses one or more read-only (non-volatile) memories, random access memories, or other re-writable (volatile) memories. A digital file attachment to email or other self-contained information archive or set of archives is considered a distribution medium equivalent to a tangible storage medium. Accordingly, the disclosure is considered to include a tangible storage medium or distribution medium, as listed herein and including art-recognized equivalents and successor media, in which the software implementations herein are stored.

The term text message or SMS refers to “short message service” which is a text messaging service component of phone, web, or mobile communication systems. It uses standardized communications protocols to allow fixed line or mobile phone devices to exchange short text messages. SMS was originally designed as part of GSM, but is now available on a wide range of networks, including 3G, 4G, LTE, 5G networks or networks associated with the communication channel as defined herein. In other aspects, text message may include Multimedia Messaging Service (MMS), which is a standard way to send messages that include multimedia content to and from mobile phones. It extends the core SMS (Short Message Service) capability that allowed exchange of text messages only up to 160 characters in length. While the most popular use is to send photographs from camera-equipped handsets, it is also used as a method of delivering news and entertainment content including videos, pictures, text pages and ringtones. Of note is that MMS messages are delivered in a completely different way from SMS. The first step is for the sending device to encode the multimedia content in a fashion similar to sending a MIME e-mail (MIME content formats are defined in the MMS Message Encapsulation specification). The message is then forwarded to the carrier's MMS store and forward server, known as the MMSC (Multimedia Messaging Service Centre). If the receiver is on another carrier, the relay forwards the message to the recipient's carrier using the Internet.

In an aspect, implementations of the power grid event analytics system 190 may be web-based. For example, a server may operate a web application to allow the disclosure to operate in conjunction with a database. The web application may be hosted in a browser-controlled environment (e.g., a Java applet and/or the like), coded in a browser-supported language (e.g., JavaScript combined with a browser-rendered markup language (e.g., Hyper Text Markup Language (HTML) and/or the like)) and/or the like such that any computer running a common web browser (e.g., Internet Explorer™′ Firefox™, Chrome™, Safari™ or the like) may render the application executable. A web-based service may be more beneficial due to the ubiquity of web browsers and the convenience of using a web browser as a client (i.e., thin client). Further, with inherent support for cross-platform compatibility, the web application may be maintained and updated without distributing and installing software on each.

Additionally, the various aspects of the disclosure may be implemented in a non-generic computer implementation. Moreover, the various aspects of the disclosure set forth herein improve the functioning of the system as is apparent from the disclosure hereof. Furthermore, the various aspects of the disclosure involve computer hardware that it specifically programmed to solve the complex problem addressed by the disclosure. Accordingly, the various aspects of the disclosure improve the functioning of the system overall in its specific implementation to perform the process set forth by the disclosure and as defined by the claims.

Aspects of the disclosure may include a server executing an instance of an application or software configured to accept requests from a client and giving responses accordingly. The server may run on any computer including dedicated computers. The computer may include at least one processing element, typically a central processing unit (CPU), and some form of memory. The processing element may carry out arithmetic and logic operations, and a sequencing and control unit may change the order of operations in response to stored information. The server may include peripheral devices that may allow information to be retrieved from an external source, and the result of operations saved and retrieved. The server may operate within a client-server architecture. The server may perform some tasks on behalf of clients. The clients may connect to the server through the network on a communication channel as defined herein. The server may use memory with error detection and correction, redundant disks, redundant power supplies and so on.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A power line event determination process implemented in a power grid comprising:
implementing a plurality of implementations of a power grid event monitor;
implementing at least one implementation of a power grid event analytics system; and
connecting the plurality of implementations of the power grid event monitor to the power grid,
wherein the power grid event monitor is a voltage monitor, a current monitor, and/or a voltage and current monitor;
wherein the plurality of implementations of the power grid event monitor are located in and electrically connected to certain respective implementations of a power grid component of the power grid; and
wherein the power grid component comprises one of the following: power stations, electrical substations, electric power transmission components, powerlines, electric power distribution components, electricity generation components, generators, high-voltage substations, local substations, high voltage transmission lines, step-up substations, step-down substations, distribution substations, transformers, circuit breakers, switches, lightning arresters, capacitors, electric power distribution components, distribution lines, distribution transformers, and/or feeders.

2. The power line event determination process according to claim 1
wherein a first implementation of the power grid event monitor is located in and/or connected to a first implementation of the power grid component of the power grid; and
wherein a second implementation of the power grid event monitor is located in and/or connected to a second implementation of the power grid component of the power grid.

3. The power line event determination process according to claim 1
wherein the power grid event monitor is configured to detect a fault criteria and generate fault data that includes a time of fault and fault criteria; and
wherein the power grid event monitor is configured to send the fault data to the power grid event analytics system.

4. The power line event determination process according to claim 3
wherein the power grid event monitor uses a GPS (Global Positioning System) or other timing methodology to generate the time of fault; and
wherein the power grid event monitor is configured to sample instantaneous voltage waveforms and/or current waveforms at a location of a respective implementation of the power grid component within the power grid that a particular implementation of the power grid event monitor is located to generate the fault criteria.

5. The power line event determination process according to claim 1 wherein the power grid event monitor is configured to sample instantaneous voltage waveforms and/or current waveforms with sub-millisecond timing accuracy.

6. The power line event determination process according to claim 3 wherein the power grid event monitor is configured to sample continuously, with triggering based on prior machine learning training information to match the fault criteria; and wherein the fault criteria includes specific signatures, traditional waveshape triggering, such as RMS (root mean square) or peak value change or trigger, waveshape change based on THD (total harmonic distortion) and/or mean square difference from previous cycle, level trigger after high pass filtering, power line frequency comb filtering, or 60 Hz comb filtering.

7. The power line event determination process according to claim 1 the power grid event analytics system is configured to utilize relative times of arrival a fault signature to estimate a fault location within the power grid.

8. The power line event determination process according to claim 1 wherein an implementation of the power grid event monitor is placed at an electrical substation at a head of each implementation of a feeder line, and an implementation of the power grid event monitor is placed at an end of the feeder line.

9. The power line event determination process according to claim 1 wherein the power grid event monitor includes a voltage transducer, a current transducer, and an ND (analog to digital) converter.

10. The power line event determination process according to claim 9
wherein the current transducer is configured to measure a current associated with the power grid component of the power grid; and
wherein the voltage transducer is configured to measure a voltage associated with the power grid component of the power grid.

11. The power line event determination process according to claim 1 wherein the power grid event monitor is configured to collect sensor readings and provide the sensor readings to the power grid event analytics system.

12. The power line event determination process according to claim 3
wherein the power grid event analytics system is implemented with a processor;
wherein the power grid event analytics system is configured to receive and parse the fault data from one or more implementations of the power grid event monitor; and
wherein the power grid event analytics system is configured process alerts from the power grid event monitor.

13. A power line event determination system implemented in a power grid comprising:
a plurality of implementations of a power grid event monitor;
at least one implementation of a power grid event analytics system; and
the plurality of implementations of the power grid event monitor connected to the power grid,
wherein the power grid event monitor is a voltage monitor, a current monitor, and/or a voltage and current monitor;
wherein the plurality of implementations of the power grid event monitor are located in and electrically connected to certain respective implementations of a power grid component of the power grid; and
wherein the power grid component comprises one of the following: power stations, electrical substations, electric power transmission components, powerlines, electric power distribution components, electricity generation components, generators, high-voltage substations, local substations, high voltage transmission lines, step-up substations, step-down substations, distribution substations, transformers, circuit breakers, switches, lightning arresters, capacitors, electric power distribution components, distribution lines, distribution transformers, and/or feeders.

14. The power line event determination system according to claim 13
wherein a first implementation of the power grid event monitor is located in and/or connected to a first implementation of the power grid component of the power grid; and
wherein a second implementation of the power grid event monitor is located in and/or connected to a second implementation of the power grid component of the power grid.

15. The power line event determination system according to claim 13
wherein the power grid event monitor is configured to detect a fault criteria and generate fault data that includes a time of fault and fault criteria; and
wherein the power grid event monitor is configured to send the fault data to the power grid event analytics system.

16. The power line event determination system according to claim 15
wherein the power grid event monitor uses a GPS (Global Positioning System) or other timing methodology to generate the time of fault; and
wherein the power grid event monitor is configured to sample instantaneous voltage waveforms and/or current waveforms at a location of a respective implementation of the power grid component within the power grid that a particular implementation of the power grid event monitor is located to generate the fault criteria.

17. The power line event determination system according to claim 13 wherein the power grid event monitor is configured to sample instantaneous voltage waveforms and/or current waveforms with sub-millisecond timing accuracy.

18. The power line event determination system according to claim 15 wherein the power grid event monitor is configured to sample continuously, with triggering based on prior machine learning training information to match the fault criteria; and wherein the fault criteria includes specific signatures, traditional waveshape triggering, such as RMS (root mean square) or peak value change or trigger, waveshape change based on THD (total harmonic distortion) and/or mean square difference from previous cycle, level trigger after high pass filtering or Hz comb filtering.

19. The power line event determination system according to claim 13 the power grid event analytics system is configured to utilize relative times of arrival a fault signature to estimate a fault location within the power grid.

20. The power line event determination system according to claim 13 wherein an implementation of the power grid event monitor is placed at an electrical substation at a head of each implementation of a feeder line, and an implementation of the power grid event monitor is placed at an end of the feeder line.

21. The power line event determination system according to claim 13 wherein the power grid event monitor includes a voltage transducer, a current transducer, and an ND (analog to digital) converter.

22. The power line event determination system according to claim 21
wherein the current transducer is configured to measure a current associated with the power grid component of the power grid; and
wherein the voltage transducer is configured to measure a voltage associated with the power grid component of the power grid.

23. The power line event determination system according to claim 13 wherein the power grid event monitor is configured to collect sensor readings and provide the sensor readings to the power grid event analytics system.

24. The power line event determination system according to claim 15
wherein the power grid event analytics system is implemented with a processor;
wherein the power grid event analytics system is configured to receive and parse the fault data from one or more implementations of the power grid event monitor; and
wherein the power grid event analytics system is configured process alerts from the power grid event monitor.
